(19) United States
(12) Patent Application Publication
(10) Pub. No.: US 2025/0180602 A1
(43) Pub. Date: Jun. 5, 2025

(54) CONTACT TERMINAL, TERMINAL ASSEMBLY, AND DEVICE TESTING APPARATUS

(71) Applicant: ADVANTEST Corporation, Tokyo (JP)

(72) Inventors: Wataru Saeki, Tokyo (JP); Yoshihiro Abe, Tokyo (JP)

(73) Assignee: ADVANTEST Corporation, Tokyo (JP)

(21) Appl. No.: 18/914,788

(22) Filed: Oct. 14, 2024

(30) Foreign Application Priority Data
Dec. 5, 2023 (JP) 2023-205563

(51) Int. Cl. G01R 1/04

(52) U.S. Cl. CPC G01R 1/0433

(57) ABSTRACT

A contact terminal includes one or more contact parts that contact a conductive member, a pressing member that presses the one or more contact parts relative to the conductive member, and an electrical connection member, independent from the pressing member, including one or more conductive paths connected to the one or more contact parts.

### CROSS-REFERENCE TO RELATED APPLICATIONS

The present application claims priority to Japanese Patent Application No. 2023-205563, filed Dec. 5, 2023. The contents of this application are incorporated herein by reference in their entirety.

### BACKGROUND

### Technical Field

The present invention relates to a contact terminal, a terminal assembly including the contact terminal, and a device testing apparatus including the terminal assembly.

### Discussion of the Background

A signal contactor that connects a flat cable and a printed circuit board is known (refer to, for example, Patent Document 1). The signal contactor has a contact point that comes into contact with the contact part of the signal layer of the flat cable and a terminal part that is connected to the connection part of the printed circuit board. The signal contactor is made of a conductive metal, and the signal contactor electrically connects the contact part of the flat cable and the connection part of the printed circuit board, while the signal contactor also functions as a spring that presses the contact point against the contact part of the flat cable.

### PATENT DOCUMENT

PATENT DOCUMENT 1: JP 2014-225412 A

The above signal contactor is a single member that performs both electrical and mechanical functions. Therefore, in the signal contactor, improving the mechanical performance may result in a decrease in electrical performance and the mechanical design may have electrical constraints.

### SUMMARY

One or more embodiments provide a contact terminal, a terminal assembly, and a device testing apparatus capable of improving a degree of freedom in designing.

An aspect 1 of one or more embodiments is a contact terminal comprising: a contact part that is contactable with a first conductive member; a pressing member that relatively presses the contact part against the first conductive member; and an electrical connection member comprising a first conductive path connected to the contact part, wherein the pressing member and the electrical connection member are mutually independent members.

An aspect 2 of one or more embodiments may be the contact terminal of the aspect 1, wherein the pressing member may comprise an elastic deformation part that is elastically deformed when the contact part is relatively pressed against the first conductive member.

An aspect 3 of one or more embodiments may be the contact terminal of the aspect 2, wherein an electrical length of the first conductive path may be constant when the elastic deformation part is deformed.

An aspect 4 of one or more embodiments may be the contact terminal of the aspect 2 or 3, wherein the electrical connection member may comprise an insulator that surrounds an entire circumference of the first conductive path.

An aspect 5 of one or more embodiments may be the contact terminal of the aspect 4, wherein the insulator may be made of a resin material.

An aspect 6 of one or more embodiments may be the contact terminal of any one of the aspects 2 to 5, wherein the elastic deformation part may comprise: a resin spring that is made of a resin material and is elastically deformed when the contact part is relatively pressed against the first conductive member; a metal spring that is made of a metal material and that is elastically deformed when the contact part is relatively pressed against the first conductive member; or an air spring that is compressed by relatively pressing the contact part against the first conductive member.

An aspect 7 of one or more embodiments may be the contact terminal of any one of the aspects 2 to 5, wherein the pressing member may be made of a resin material, and the elastic deformation part may comprise a resin spring that is elastically deformed when the contact part is relatively pressed against the first conductive member.

An aspect 8 of one or more embodiments may be the contact terminal of the aspect 7, wherein the contact terminal may comprise a plurality of the contact parts, the electrical connection member may comprise a plurality of the first conductive paths that are connected to the plurality of contact parts, the pressing member may comprise a plurality of the elastic deformation parts that correspond to the plurality of contact parts; and the plurality of elastic deformation parts may be integrally formed.

An aspect 9 of one or more embodiments may be the contact terminal of any one of the aspects 1 to 8, wherein the contact terminal may comprise a plurality of the contact parts, the electrical connection member may include a flexible printed circuit board having flexibility, and the flexible printed circuit board may comprise a plurality of the first conductive paths that are connected to the plurality of contact parts.

An aspect 10 of one or more embodiments may be the contact terminal of the aspect 9, wherein the flexible printed circuit board may comprise: a first insulating layer; the plurality of first conductive paths that are disposed on the first insulating layer; and a second insulating layer that is laid on the first insulating layer so that the second insulating layer covers the plurality of first conductive paths.

An aspect 11 of one or more embodiments may be the contact terminal of the aspect 10, wherein the plurality of first conductive paths may be arranged on the first insulating layer with a space between the plurality of first conductive paths.

An aspect 12 of one or more embodiments may be the contact terminal of the aspect 10 or 11, wherein the flexible printed circuit board may have a slit that is disposed between the plurality of first conductive paths.

An aspect 13 of one or more embodiments may be the contact terminal of the aspect 12, wherein the slit may penetrate at least one of the first and second insulating layers.

An aspect 14 of one or more embodiments may be the contact terminal of the aspect 12 or 13, wherein the slit may penetrate the flexible printed circuit board.

An aspect 15 of one or more embodiments may be the contact terminal of any one of the aspects 11 to 14, wherein the plurality of first conductive paths may include: a plurality of ground lines; and a plurality of signal lines that are respectively disposed between the plurality of ground lines.

An aspect 16 of one or more embodiments may be the contact terminal of the aspect 15, wherein the flexible printed circuit board may comprise a first ground layer that is disposed on the first insulating layer and faces the signal line via the first insulating layer.

An aspect 17 of one or more embodiments may be the contact terminal of the aspect 15 or 16, wherein the flexible printed circuit board may comprise a second ground layer that is disposed on the second insulating layer and faces the signal line via the second insulating layer.

An aspect 18 of one or more embodiments may be the contact terminal of any one of the aspects 15 to 17, wherein the plurality of contact parts may include: a signal contact part that is connected to the signal line; and a ground contact part that is connected to the ground line.

An aspect 19 of one or more embodiments may be the contact terminal of the aspect 18, wherein the contact terminal may comprises a third ground layer that is electrically connected to the ground contact part, the pressing member may have a through hole through which the signal contact part passes, and the third ground layer may be disposed in the through hole so that the third ground layer faces the signal contact part with a gap.

An aspect 20 of one or more embodiments may be the contact terminal of any one of the aspects 1 to 19, wherein the contact part may comprise a metal layer that is held by the pressing member, and the metal layer may be disposed on a front end part of the pressing member.

An aspect 21 of one or more embodiments may be the contact terminal of the aspect 20, wherein the pressing member may comprise an elastic deformation part that is elastically deformed when the contact part is relatively pressed against the first conductive member, and the contact part may be disposed on the front end part included in the elastic deformation part.

An aspect 22 of one or more embodiments may be the contact terminal of the aspect 20 or 21, wherein the metal layer may extend linearly in the front end part, and a following formula (1) may be satisfied,

$$Lb < La \times 1 / 10 \qquad ( 1 )$$

wherein, in the formula (1), La may be a length of the first conductive path, and Lb may be a length of the metal layer.

An aspect 23 of one or more embodiments may be the contact terminal of any one of the aspects 20 to 22, wherein the contact terminal may comprise a plurality of the contact parts, and the plurality of contact parts may be disposed on the single front end part.

An aspect 24 of one or more embodiments may be the contact terminal of any one of the aspects 1 to 23, wherein the pressing member may comprise: an elastic deformation part that is elastically deformed when the contact part is relatively pressed against the first conductive member; and a supporting part that supports the elastic deformation part.

An aspect 25 of one or more embodiments may be the contact terminal of the aspect 24, wherein the pressing member may be made of a resin material, and the elastic deformation part and the supporting part may be integrally formed.

An aspect 26 of one or more embodiments may be the contact terminal of the aspect 24 or 25, wherein a virtual line that passes through a front end of the pressing member and is parallel to a center line of the supporting part may be shifted from the center line.

An aspect 27 of one or more embodiments may be the contact terminal of any one of the aspects 1 to 26, wherein the pressing member may comprise: an elastic deformation part that is elastically deformed when the contact part is relatively pressed against the first conductive member; and a deformation limiting part that limits an elastic deformation of the elastic deformation part by contacting the first conductive member.

An aspect 28 of one or more embodiments may be the contact terminal of the aspect 27, wherein the pressing member may be made of a resin material, and the elastic deformation part and the deformation limiting part may be integrally formed.

An aspect 29 of one or more embodiments may be the contact terminal of the aspect 28, wherein the pressing member may comprise a supporting part that supports the elastic deformation part and the deformation limiting part, and the elastic deformation part, the deformation limiting part, and the supporting part may be integrally formed.

An aspect 30 of one or more embodiments may be the contact terminal of any one of the aspects 1 to 29, wherein the contact part may come into contact with the first conductive member as the contact terminal relatively moves with respect to the first conductive member.

An aspect 31 of one or more embodiments may be the contact terminal of the aspect 30, wherein a pressing direction of the contact part by the pressing member is parallel to a direction of relative movement of the contact terminal with respect to the first conductive member.

An aspect 32 of one or more embodiments may be the contact terminal of any one of the aspects 1 to 31, wherein the signal passing through the first conductive path may be a high-frequency signal of 1 GHz or more.

An aspect 33 of one or more embodiments may be the contact terminal of any one of the aspects 1 to 32, wherein the contact terminal may be a terminal that electrically connects the first conductive member and a second conductive member, and the first conductive path may be electrically connected to the second conductive member.

An aspect 34 of one or more embodiments is a terminal assembly comprising: a plurality of the contact terminals of any one of the aspects 1 to 33; and a supporting member that supports the plurality of contact terminals.

An aspect 35 of one or more embodiments may be the terminal assembly of the aspect 34, wherein the supporting member may comprise a wiring board comprising a second conductive path, and the first conductive path may be connected to the second conductive path.

An aspect 36 of one or more embodiments may be the terminal assembly of the aspect 35, wherein a second conductive member may be connected to the second conductive path.

An aspect 37 of one or more embodiments may be the terminal assembly of any one of the aspects 34 to 36, wherein the plurality of contact terminals may be disposed so that the pressing members face each other.

An aspect 38 of one or more embodiments is a device testing apparatus the tests a device under test (DUT), the device testing apparatus comprising: a first conductive member; a second conductive member; and the terminal assembly of any one of the aspects 34 to 37, wherein the first conductive path of the contact terminal is electrically connected to the second conductive member, and the contact terminal electrically connects the first conductive member and the second conductive member.

In one or more embodiments, because the pressing member and the electrical connection member are independent of each other, it is possible to reduce the mutual constraints between the designing of the pressing member and the designing of the electrical connection member, and it is possible to improve the degree of freedom in the designing of the contact terminal.

### BRIEF DESCRIPTION OF THE DRAWINGS

FIG. 1 is a schematic cross-sectional view showing the overall configuration of the device testing apparatus in one or more embodiments.

FIG. 2 is an exploded sectional view showing the DSA and the motherboard in one or more embodiments and is a view corresponding to the section II in FIG. 1.

FIG. 3 is a perspective view of the terminal assembly from the front side in one or more embodiments.

FIG. 4 is a perspective view of the terminal assembly from the rear side in one or more embodiments.

FIG. 5 is a cross-sectional view showing the terminal assembly in one or more embodiments and is a view taken along line V-V in FIG. 3.

FIG. 6 is a plan view showing the contact terminal and the wiring board in one or more embodiments.

FIG. 7 is an exploded perspective view showing the contact terminal in one or more embodiments.

FIG. 8 is a side view showing the pressing member in one or more embodiments.

FIG. 9 is a bottom view showing the electrical connection member in one or more embodiments.

FIG. 10 is a partial cross-sectional view showing the electrical connection member in one or more embodiments and is a view taken along line X-X in FIG. 9.

FIG. 11 is a partial cross-sectional view showing a first modification of the electrical connection member in one or more embodiments.

FIG. 12 is a plan view showing a second modification of the electrical connection member in one or more embodiments.

FIG. 13 is a perspective view showing the contact part formed on the front end part of the pressing member in one or more embodiments.

FIG. 14 is a cross-sectional view showing the front end part of the pressing member in one or more embodiments and is a view taken along line XIV-XIV in FIG. 13.

FIG. 15A, FIG. 15B, and FIG. 15C are cross-sectional views showing the first to third modifications of the contact terminal.

### DESCRIPTION OF THE EMBODIMENTS

Hereinafter, embodiments will be described with reference to the drawings.

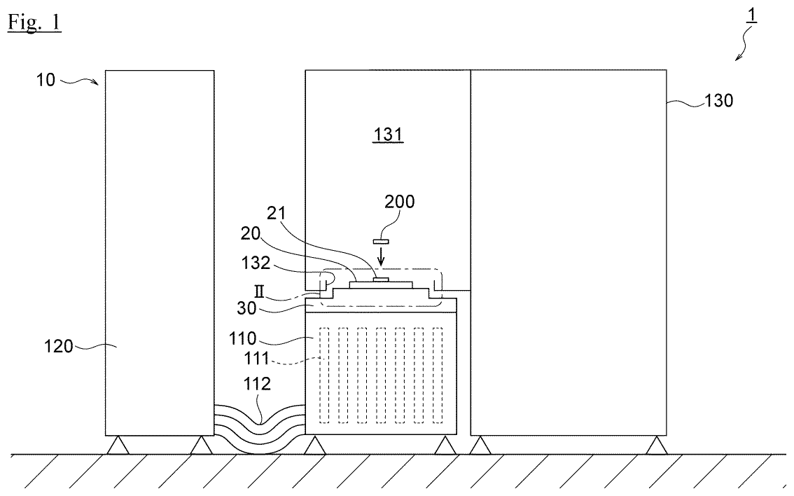

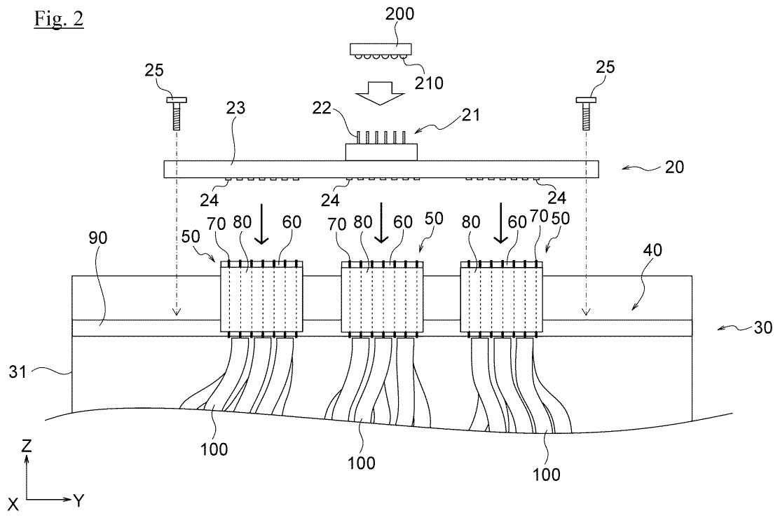

FIG. 1 is a schematic cross-sectional view showing the overall configuration of the device testing apparatus 1 in one or more embodiments, and FIG. 2 is an exploded sectional view showing the DSA 20 and the motherboard 30 in one or more embodiments and is a view corresponding to the section II in FIG. 1.

The device testing apparatus 1 in one or more embodiments is an apparatus that tests a device under test (hereinafter also simply referred to as “DUT”) 200. Although not particularly limited, a semiconductor device such as a memory device, a logic device, and SoC (System on chip) can be exemplified as a specific example of the DUT 200 to be tested. The device testing apparatus 1 is an apparatus that tests the electrical characteristics of the DUT 200.

As shown in FIG. 1, the device testing apparatus 1 includes a tester 10 that tests the DUT 200, and a handler 130 that handles the DUT 200 and presses the DUT 200 against a socket 21. The tester 10 includes a DSA20, a motherboard 30, a test head 110, and a main frame 120. The configuration of the tester 10 is not particularly limited to the following as long as it includes the terminal assembly 40 describer later.

As shown in FIG. 1 and FIG. 2, the DSA (Device Specific Adapter) 20 includes a socket 21 and a wiring board 23. The DSA 20 is electrically connected to the test head 110 via the motherboard 30. The DSA 20 is detachable from the motherboard 30. The DSA 20 is designed according to the type of the DUT 200, and the DSA 20 is replaced with one corresponding to the type when changing the type of DUT 200. The number of DSAs 20 mounted on the motherboard 30 is not particularly limited, and a plurality of DSAs 20 may be mounted on the motherboard 30.

When testing the DUT 200, the DUT 200 is pressed against the socket 21 by the handler 130, therefore the DUT 200 and the socket 21 are electrically connected. The socket 21 includes a plurality of contactors 22 that respectively contact terminals 210 of the DUT 200. Although not particularly limited, a pogo pin, a vertical-type probe needle, a cantilever-type probe needle, an anisotropic conductive rubber sheet, a bump disposed on a membrane, or a contactor manufactured using MEMS technology can be exemplified as a specific example of the contactor 22.

The wiring board 23 is a rigid wiring board with the above-described socket 21 mounted on its upper surface. Although not particularly illustrated, a socket guide for positioning the DUT 200 with respect to the socket 21 may be attached to the socket 21. The wiring board 23 has a plurality of pads 24 on the lower surface of the wiring board 23. The plurality of pads 24 is disposed on the lower surface of the wiring board 23 to correspond to a plurality of contact parts 70 (described later) of the terminal assembly 40 of the motherboard 30. The socket 21 and the pad 24 are electrically connected via a conductive path (not shown) such as a wiring pattern and a through hole formed in the wiring board 23.

Although only one socket 21 is mounted on the wiring board 23 in FIG. 1 and FIG. 2, in reality, a large number of sockets 21 are mounted on a single wiring board 23. Therefore, in one or more embodiments, tens of thousands of pads 24 are disposed on the lower surface of wiring board 23. The wiring board 23 of one or more embodiments has a size of, for example, approximately 1200 mm×500 mm. The number of pads 24 on the wiring board 23 and the size of the wiring board 23 are not limited to those mentioned above.

The motherboard 30 is a relaying device that electrically connects the DSA 20 and the test head 110. The motherboard 30 includes a housing 31, terminal assemblies 40, and coaxial cables 100. One end (the upper end in FIG. 2) of the coaxial cable 100 is connected to the wiring board 90 (described later) of the terminal assembly 40. When the DSA 20 is attached to the motherboard 30, the contact part 70 of the terminal assembly 40 is pressed against the pad 24 of the DSA 20, and the contact part 70 comes into contact with the pad 24, therefore the wiring board 23 of the DSA 20 and the coaxial cable 100 are electrically connected. The configuration of the terminal assembly 40 will be described in detail later.

As shown in FIG. 1, the test head 110 accommodates therein a test module (pin electronics card) 111 for testing the DUT 200. The test module 111 is a wiring board on which electronic components such as test devices used for testing the DUT 200 are mounted. The test module 111 is electrically connected to the coaxial cable 100 of the motherboard 30 via a connector (not shown) or the like connected to the other end of the coaxial cable 100. The test module 111 tests the DUT 200 by transmitting and receiving test signals to and from the DUT 200 via the DSA 20 and the motherboard 30. The test head 110 is connected to the main frame 120 via a cable 112.

The main frame (tester main body) 120 is, for example, a computer that executes a program, and the main frame 120 communicates with the test modules 111 in the test head 110 according to the program to control the test modules 111. Each of the test module 111 generates test signals according to instructions from the main frame 120 and outputs the test signals to the DUT 200.

Although not particularly illustrated, the handler 130 includes, for example, a transport device that transports the test tray on which the DUT 200 is mounted above the DSA 20, a pressing device that presses the DUT 200 against the socket 21 of the DSA 20, and a sorting device that sorts the DUT 200 according to the test result while taking the DUT 200 out from the test tray.

The handler 130 also includes a chamber 131 as a temperature adjusting device that applies high or low temperature thermal stress to the DUT 200. The chamber 131 includes a thermostatic chamber capable of maintaining the temperature in the chamber at a desired temperature. Therefore, the device testing apparatus 1 is capable of testing the DUT 200 while applying thermal stress to the DUT 200, and a so-called high-temperature test and a low-temperature test can be performed.

The DSA 20 enters the chamber 131 through an opening 132 formed in the handler 130, and the socket 21 of the DSA 20 is disposed in the chamber 131. The pressing device of the handler 130 presses the DUT 200 against the socket 21 of the DSA 20 to electrically connect the DUT 200 and the socket 21.

The handler 130 may be of a type where the handler 130 includes a contact arm that suction-holds and moves the DUT 200 without using a test tray and the contact arm presses the DUT 200. In this case, the handler 130 may include a heater or a heat sink disposed in the front end of the contact arm as a temperature adjusting device instead of the chamber 131. Alternatively, the handler 130 may include, in addition to the chamber 131, a heater or a heat sink disposed in the front end of the contact arm as a temperature adjusting device.

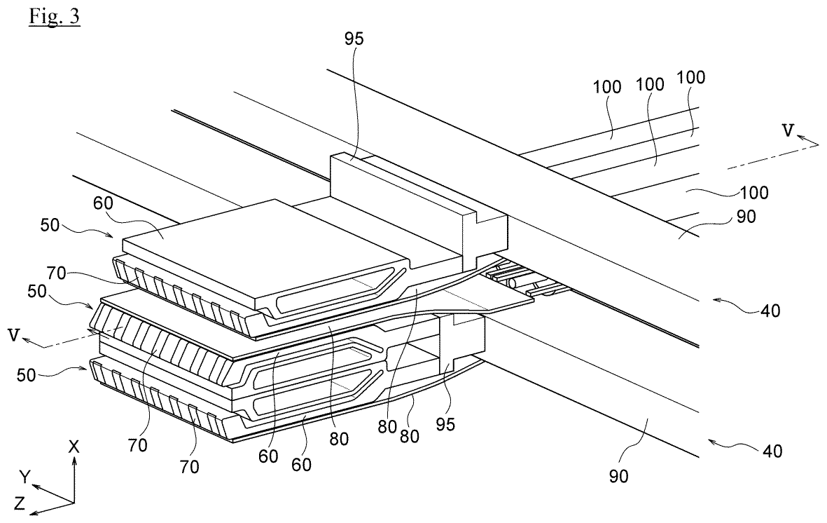

Next, the configuration of the terminal assembly 40 included in the motherboard 30 described above will be described in detail with reference to FIG. 3 to FIG. 10.

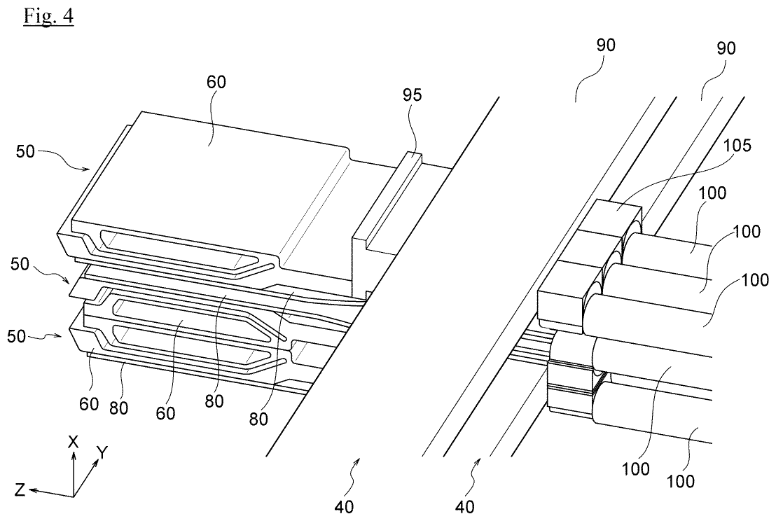

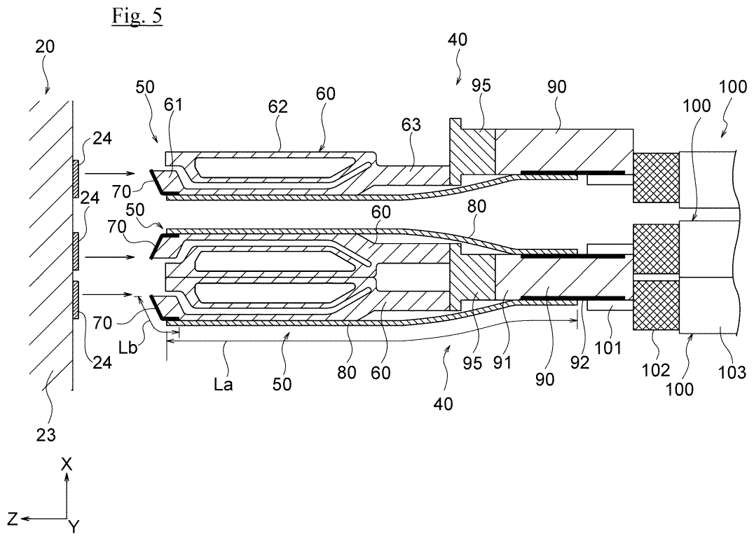

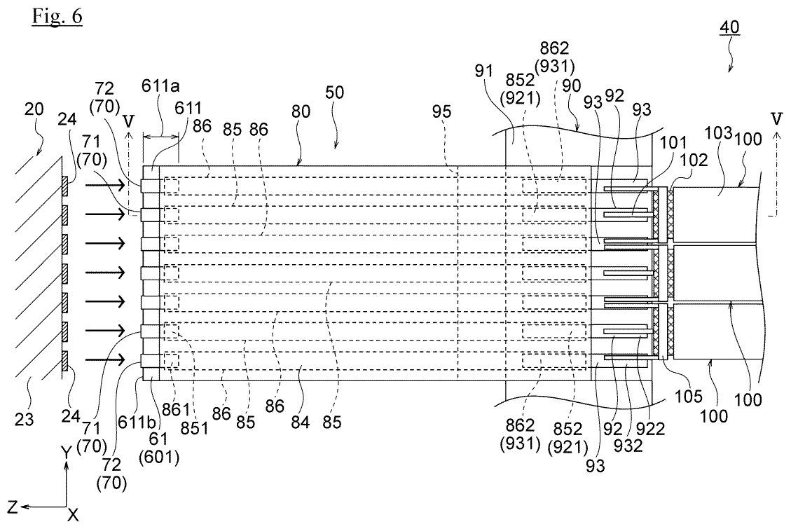

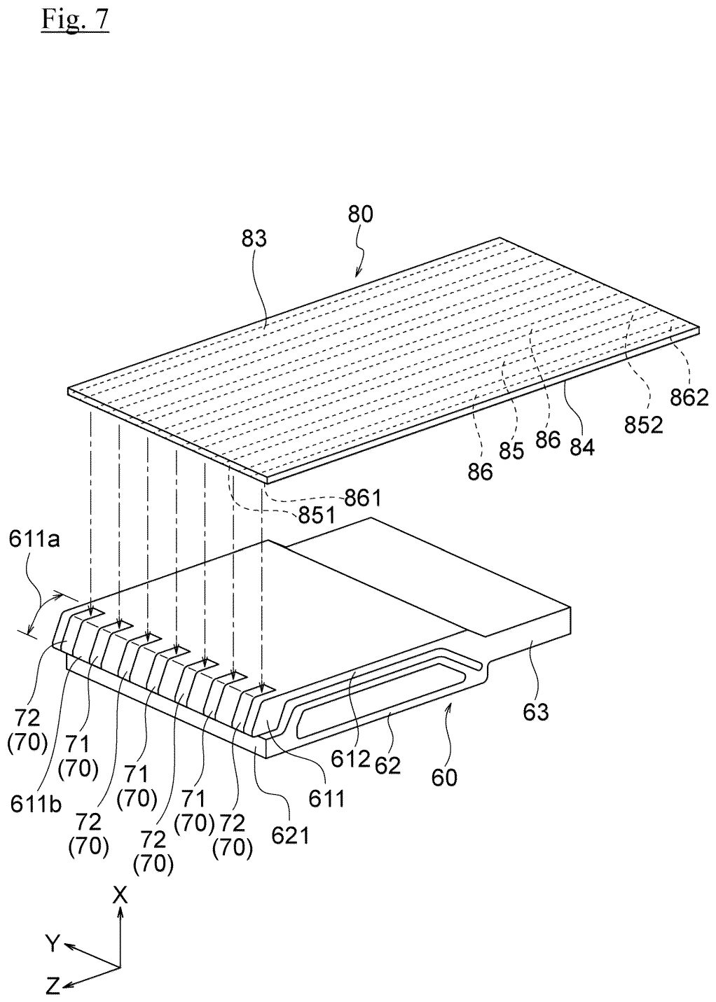

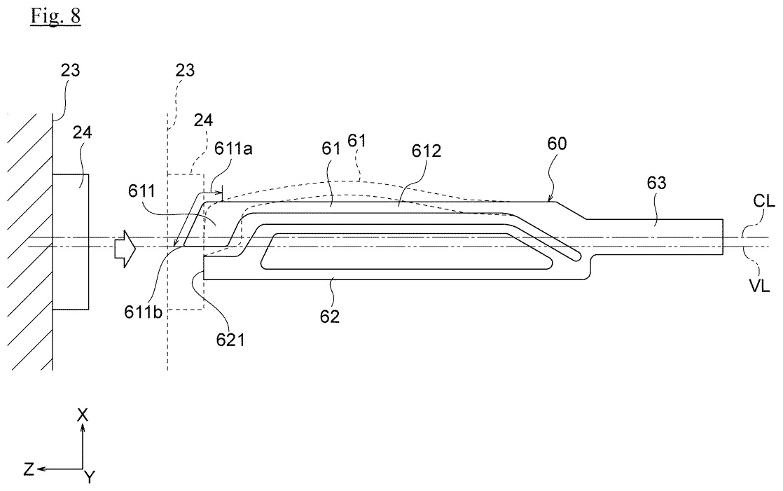

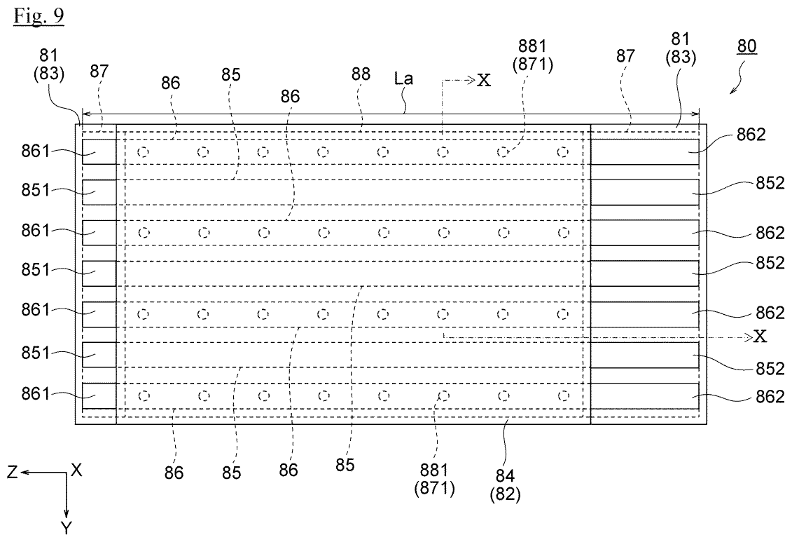

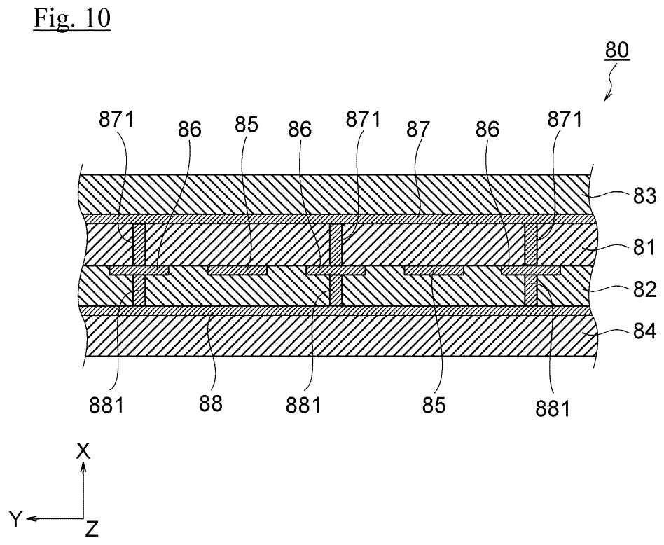

FIG. 3 is a perspective view of the terminal assembly 40 from the front side in one or more embodiments, and FIG. 4 is a perspective view of the terminal assembly 40 from the rear side in one or more embodiments. FIG. 5 is a cross-sectional view showing the terminal assembly 40 in one or more embodiments and is a view taken along line V-V in FIG. 3. FIG. 6 is a plan view showing the contact terminal 50 and the wiring board 90 in one or more embodiments, and FIG. 7 is an exploded perspective view showing the contact terminal 50 in one or more embodiments. FIG. 8 is a side view showing the pressing member 60 in one or more embodiments. FIG. 9 is a bottom view showing the electrical connection member 80 in one or more embodiments. FIG. 10 is a partial cross-sectional view showing the electrical connection member 80 in one or more embodiments and is a view taken along line X-X in FIG. 9.

As shown in FIG. 3 to FIG. 5, the mother board 30 includes the plurality of terminal assemblies 40. As described above, the terminal assemblies 40 electrically connect the pads 24 of the wiring board 23 of the DSA 20 and the coaxial cables 100 of the mother board 30. The wiring board 23 corresponds to an example of the “first conductive member” in the aspects of one or more embodiments, and the coaxial cable 100 corresponds to an example of the “second conductive member” in the aspects of one or more embodiments. Each of the terminal assemblies 40 includes contact terminals 50 and wiring board (example of a supporting member) 90 that supports the contact terminals 50.

In FIG. 3 to FIG. 5, only two terminal assemblies 40 are shown, and each of the terminal assemblies 40 includes only one or two contact terminals 50. However, in reality, the mother board 30 includes a large number of terminal assemblies 40 each of which has a large number of contact terminals 50, and as a result, the motherboard 30 includes the number (tens of thousands in one or more embodiments) of contact parts 70 corresponding to the number of pads 24 included in the DSA 20.

As shown in FIG. 5 to FIG. 7, the contact terminal 50 includes a pressing member 60, contact parts 70, and an electrical connection member 80. The contact part 70 is contactable with and separatable from the pad 24 of the wiring board 23 of the DSA 20 described above. The pressing member 60 holds the contact parts 70 on the front end part 611 of the pressing member 60, the pressing member 60 relatively presses (applies pressure to) the contact part 70 against the pad 24. In one or more embodiments, when the pad 24 is pressed against the contact part 70, the pressing member 60 pushes back the contact part 70 towards the pad 24. The electrical connection member 80 is connected to the contact part 70 and is electrically connected to the coaxial cable 100 via the wiring board 90. Since all of the contact terminals 50 included in the motherboard 30 basically have the same configuration, the configuration of the central contact terminal 50 among the three contact terminals 50 shown in FIG. 5 will be representatively described.

As shown in FIG. 7 and FIG. 8, the pressing member 60 includes an elastic deformation part 61, a deformation limiting part 62 and supporting part 63. The pressing member 60 is made of a material that is electrically insulating and is elastically deformable. Although not particularly limited, a resin material can be exemplified as a specific example of a material of which the pressing member 60 is made. The elastic deformation part 61, the deformation limiting part 62, and the supporting part 63 are integrally formed by resin molding. The pressing member 60 may also be made of a metal material. In this case, an insulating layer is formed by applying an insulating treatment to the surface of the pressing member 60.

On the other hand, as described below, the electrical connection member 80 is a flexible printed circuit board. Therefore, in one or more embodiments, the pressing member 60 and the electrical connection member 80 are configured as completely independent (meaning not integrated) members (components). In this way, by making the pressing member 60 and the electrical connection member 80 independent of each other, it is possible to minimize electrical constraints on the mechanical design, and it is possible to freely design pressing member 60. For example, it is possible to lengthen the spring stroke (the amount of elastic possible deformation along the Z direction in the figure) of the pressing member 60 while minimizing the impact on electrical performance, therefore it is possible to expand the range in which height variations in the pads 24 due to warping or processing accuracy of the wiring board 23 of the DSA 20 can be absorbed.

Furthermore, when performing low-temperature testing (for example, testing the DUT at −50° C. to −40° C.) in the device testing apparatus, if the contact terminal is made of a metal material, heat may be transferred into the inside of the motherboard via the conductor of the coaxial cable and the contact terminal, there is a risk that the dew condensation occurs to the inside of the motherboard due to cooling. On the other hand, since the pressing member 60 is made of a resin material, it is possible to suppress the heat transfer from the chamber 131 of the handler 130 to the inside of the motherboard 30, and it is possible to prevent the dew condensation from occurring to the inside of the motherboard 30. In addition, since the Young's modulus of the resin material is relatively low, it is possible to ensure a large spring stroke even in a small space.

The elastic deformation part 61 is a portion extending in the pressing direction (Z direction in the figure) of the pressing member 60. The deformation limiting part 62 is also a portion extending in the pressing direction (Z direction in the figure) of the pressing member 60. The rear end part (the end part on the −Z side in the figure) of the elastic deformation part 61 is connected to the supporting part 63, and the rear end part (the end part on the −Z side in the figure) of the deformation limiting part 62 is also connected to the supporting part 63. In other words, the elastic deformation part 61 and the deformation limiting part 62 are supported by the supporting part 63. Since the pad 24 side (the +Z side in the figure) is the front and the coaxial cable 100 side is the rear (the −Z side in the figure) in the contact terminal 50, the above pressing direction is also the front-to-rear direction of the contact terminal 50.

As shown in FIG. 6 and FIG. 7, the plurality of (seven in one or more embodiments) contact parts 70 are disposed on the front end part 611 of the elastic deformation part 61. Each of the contact parts 70 extends linearly from the front end 611b of the front end part 611 toward the rear of the elastic deformation part 61, and the contact part (example of a metal layer) 70 has a length Lb (refer to FIG. 5). The plurality of contact parts 70 are disposed with spaces between the plurality of contact parts 70. The number of contact parts 70 included in the contact terminal 50 is not particularly limited to the above.

Each of the contact parts 70 is a thin film formed on the front end region 611a that is the surface of the front end part 611. The front end region 611a is a region that extends rearward from the front end 611b in the frond end part 611 of the elastic deformation part 61. The front end 611b is included in the front end region 611a. The thin film is made of a material having electrical conductivity. Although not particularly limited, metal materials such as copper can be exemplified as a specific example of the material of which the contact part 70 is made. The thin film is, for example, a plated layer formed by a plating method such as electrolytic plating or electroless plating. The method of forming the thin film of the contact part 70 is not limited to the above-described plating method. The contact part 70 may be formed by, for example, physical vapor deposition method (PVD) such as vacuum deposition or sputtering, or chemical vapor deposition method (CVD).

The contact part 70 may be formed of a metal foil instead of the thin film described above. Although not particularly limited, a copper foil and a silver-plated copper foil can be exemplified as a specific example of the metal foil constituting the contact part 70. In this case, the pressing member 60 and the contact part 70 are integrated by insert molding. Alternatively, the contact part 70 may be fixed to the pressing member 60 by an adhesive.

In one or more embodiments, the plurality of contact parts 70 include three signal contact parts 71 and four ground contact parts 72. Each of the signal contact parts 71 is disposed between the ground contact parts 72. The signal contact part 71 is connected to a signal line 85 (described later and example of a conductive path or a first conductive path) of the electrical connection member 80. On the other hand, the ground contact part 72 is connected to a ground line 86 (described later and example of the conductive path or a first conductive path) of the electrical connection member 80.

As shown in FIG. 8, the elastic deformation part 61 is a leaf spring having a substantially bow-like (substantially arc-like) shape that protrudes in the +X direction in the figure as a whole. The elastic deformation part 61 includes the above-described front end part 611 on which the contact part 70 is disposed, and a spring part 612 that is elastically deformed to press the front end part 611 toward the pad 24. The front end part 611 and the spring part 612 are integrally formed. The front end part 611 holds the plurality of contact parts 70. That is, the plurality of contact parts 70 are disposed on a single (one) frond end part 611 (the same front end part 611). Therefore, it is possible to ensure the relative positional relationship between the contact parts 70, and it is possible to suppress the occurrence of a short circuit between the adjacent pads 24 via the contact part 70. As shown by the dashed line in FIG. 8, the spring part 612 of the elastic deformation part 61 can be elastically deformed when the front end 611b of the elastic deformation part 61 is pressed by the pad 24. That is, the elastic deformation part 61 includes a resin spring. On the other hand, when the pressing member 60 is made of a metal material, the elastic deformation part 61 includes a metal spring. The contact part 70 is omitted in FIG. 8.

Here, as shown in FIG. 8, the virtual line VL passing through the front end 611b of the elastic deformation part 61 is shifted (offset) from the center line CL of the supporting part 63. More specifically, the virtual line VL is shifted from the center line CL in the direction (the −X direction in the figure) opposite to the direction in which the bow-like shape of the elastic deformation part 61 protrudes. Therefore, the contact part 70 can be rubbed (scrubbed) against the pad 24, and it is possible to ensure good electrical connection between the contact terminal 50 and the pad 24. Both of the virtual line VL and center line CL are straight lines parallel to the pressing direction (the Z direction in the figure) of the pressing member 60.

The deformation limiting part 62 has an abutting part 621 at the front end of the deformation limiting part 62. The abutting part 621 is located closer to the rear end side (the −Z direction side in the figure) than the front end 611b of the elastic deformation part 61. As shown by the dashed line in FIG. 8, when the front end 611b of the elastic deformation part 61 is pressed by the pad 24, the abutting part 621 abuts against the pad 24 to suppress damage to the elastic deformation part 61 due to excessive deformation.

In one or more embodiments, a plurality of pressing members that individually hold the plurality of contact parts 70 are integrated as the single pressing member 60. Therefore, it is possible to ensure the relative positional relationship between the contact parts 70 with high accuracy, and it is possible to suppress the occurrence of a short circuit between the adjacent pads 24 via the contact portions 70. Further, it is possible to reduce the cost of the contact terminal 50 by integrally forming the plurality of pressing members as the single pressing member 60 using a resin material. The contact terminal 50 may include a plurality of pressing members that individually hold a plurality of contact parts 70. Alternatively, for example, the pressing member may include a plurality of elastic deformation parts that individually hold the plurality of contact parts 70, the plurality of deformation limiting parts may be integrated as the single deformation limiting part 62, the plurality of support parts may also be integrated as the single supporting part 63, and the plurality of elastic deformation parts and the single deformation limiting part 62 may be supported by the single supporting part 63.

The electrical connection member 80 is a single flexible printed circuit board (FPC) that has flexibility. In one or more embodiments, since the pressing member 60 and the electrical connection member 80 are mutually independent members as described above, it is possible to use an FPC as the electrical connection member 80, and a transmission line with transmission performance for transmitting high-frequency signals can be designed independently of the design of the pressing member 60.

As shown in FIG. 9 and FIG. 10, the electrical connection member 80 (hereinafter also referred to simply as “FPC 80”) includes first to fourth insulating layers 81 to 84, a plurality of (three in one or more embodiments) signal lines 85, a plurality of (four in one or more embodiments) ground lines 86, and first and second ground layers 87 and 88.

Each of the first to fourth insulating layers 81 to 84 is a flexible film made of an electrically insulating material. For example, polyimide (PI), liquid crystal polymer (LCP), and polyethylene terephthalate (PET) can be exemplified as a specific example of the materials of which the first to fourth insulating layers 81 to 84 are made.

As shown in FIG. 10, the signal lines 85 and the ground lines 86 are disposed on the lower surface of the first insulating layer 81. The signal line 85 functions as a transmission path for transmitting an electrical signal between the test head 110 and the DUT 200. On the other hand, the ground line 86 is connected to the ground and functions as an electromagnetic shielding layer for blocking noise. In the device testing apparatus 1 described above, the electrical signal passing through the signal line 85 is a high frequency electrical signal and is an electrical signal with a frequency of 1 GHz or more, or an electrical signal with a frequency of 10 GHz or more.

The signal lines 85 and the ground lines 86 are formed, for example, by etching the copper foil laid on the first insulating layer 81 into a predetermined shape. As shown in FIG. 6, FIG. 7, and FIG. 9, the signal lines 85 and the ground lines 86 extend linearly from the front side (the +Z direction side in the figure) end to the rear side (−Z direction side in the figure) end of the electrical connecting member 80 and each of the signal lines 85 and the ground lines 86 has a length La (refer to FIG. 5 and FIG. 9).

The number of lines 85 and 86 included in the FPC 80 is not particularly limited to the above and can be set according to, for example, the number of contact parts 70 included in the contact terminal 50. Further, the shape and arrangement of the lines 85 and 86 included in the FPC 80 are not particularly limited to the above. Instead of replacing (swapping) the coaxial cable 100, the shape and arrangement of the lines 85 and 86 of the FPC 80 may be changed.

As shown in FIG. 10, the second insulating layer 82 is laid on the lower surface of the first insulating layer 81 so that the second insulating layer 82 covers the signal lines 85 and the ground lines 86. The signal line 85 and the ground line 86 are disposed with a space between the signal line 85 and the ground line 86. Therefore, the signal line 85 is surrounded by a resin material (insulator) over the entire circumference of the signal line 85. The first insulating layer 81 and the second insulating layer 82 may be bonded together by an adhesive having electrical insulating properties.

In one or more embodiments, since the entire circumference of the signal line 85 is surrounded by the resin material, even if the spring stroke of the pressing member 60 is lengthened, the dielectric constant and the thickness of the insulator existing around the signal line 85 do not change. Therefore, since the electrical length of the signal line 85 is always constant even when the pressing member 60 is elastically deformed, and it is possible to suppress the variation in impedance in the signal line 85, it is possible to suppress the variation in the transmission characteristics among a large number of signal lines 85. Further, since the entire circumference of the signal line 85 is surrounded by the resin material, it is possible to suppress the occurrence of a leakage current between the signal line 85 and the ground line 86.

The first ground layer 87 is disposed on the upper surface of the first insulating layer 81. Furthermore, the third insulating layer 83 is laid on the upper surface of the first insulating layer 81 so that the third insulating layer 83 covers the first ground layer 87. The first insulating layer 81 and the third insulating layer 83 may be bonded together by an adhesive having electrical insulating properties. The first ground layer 87 is a so-called solid pattern and is formed by etching a copper foil into a predetermined shape. The first ground layer 87 faces the signal lines 85 via the first insulating layer 81. The first ground layer 87 is electrically connected to the ground line 86 via a through hole 871 and functions as an electromagnetic shielding layer for blocking noise.

On the other hand, the second ground layer 88 is disposed on the lower surface of the second insulating layer 82. Furthermore, the fourth insulating layer 84 is laid on the lower surface of the second insulating layer 82 so that the fourth insulating layer 84 covers the second ground layer 88. The second insulating layer 82 and the fourth insulating layer 84 may be bonded together by an adhesive having electrical insulating properties. The second ground layer 88 is a so-called solid pattern and is formed by etching a copper foil into a predetermined shape. The second ground layer 88 faces the signal lines 85 via the second insulating layer 82. The second ground layer 88 is electrically connected to the ground line 86 via a through hole 881 and functions as an electromagnetic shielding layer for blocking noise.

As described above, the FPC 80 of one or more embodiments has a strip line structure in which the signal line 85 is surrounded on all four sides by the ground lines 86 and the ground layers 87 and 88. Thus, it is possible to ensure good shielding performance, it is possible to suppress the occurrence of crosstalk between the signal lines 85 even if the spring stroke of the pressing member 60 is lengthened, and it is possible to suppress the variation in the transmission characteristics among a large number of signal lines 85. Further, since it is possible to suppress a decrease in the crosstalk characteristics even when the signal lines 85 are disposed on the motherboard 30 at a high density, it is possible to achieve both a high density and a wide bandwidth. In addition, in one or more embodiments, since the electrical connecting member 80 is the FPC, it is possible to reduce the cost of the contact terminal 50 including the lines disposed in high density.

Here, as shown in following formula (2) below, the length Lb (refer to FIG. 5) of the above-described signal contacting part (example of a metal layer) 71 is less than 1/10 of the length La (refer to FIG. 5 and FIG. 9) of the signal line 85 in the FPC 80. That is, in one or more embodiments, since the strip line structure is maintained up to the closest position to the pad 24, it is possible to ensure good shielding performance.

$$Lb < La \times 1 / 10 \qquad ( 2 )$$

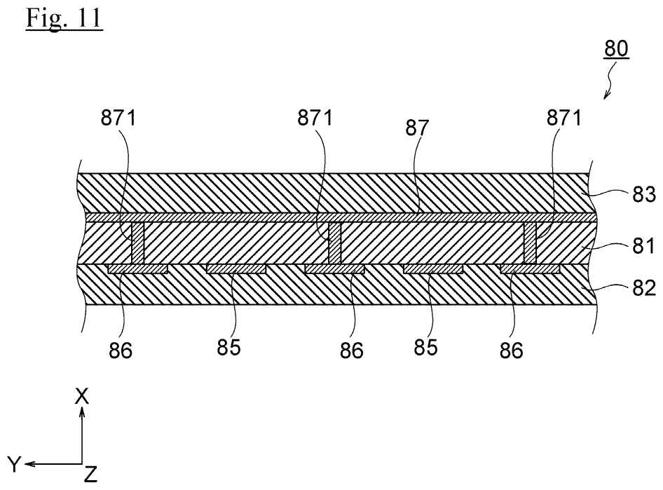

The structure of the FPC 80 is not limited to the above, and the FPC 80 may have a microstrip line structure as shown in FIG. 11. FIG. 11 is a partial cross-sectional view showing the first modification of the electrical connection member 80 in one or more embodiments. The FPC 80 shown in FIG. 11 is different from the FPC 80 shown in FIG. 10 in that it does not include the fourth insulating layer 84, the second ground layer 88, and the through hole 881.

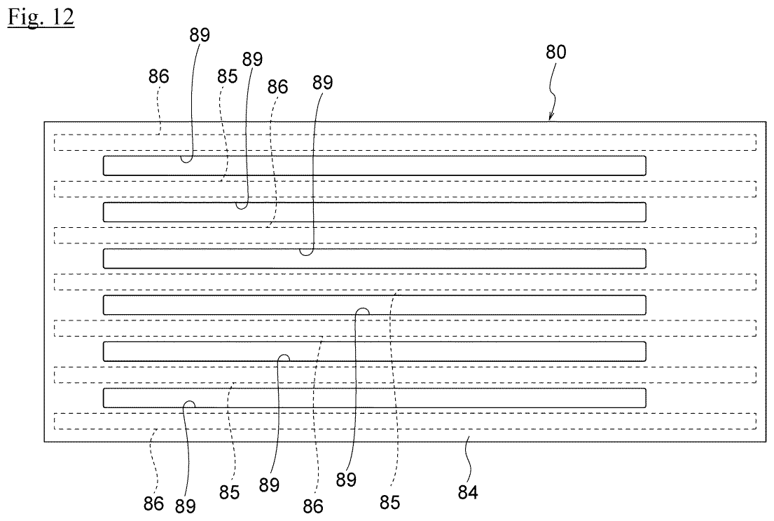

Furthermore, as shown in FIG. 12, the FPC 80 may have slits 89. FIG. 12 is a plan view showing the second modification of the electrical connection member 80 in one or more embodiments. Each of the slits 89 is disposed between the signal line 85 and the ground line 86 and penetrates the first to fourth insulating layers 81 to 84 in their thickness direction. Therefore, it possible to make the FPC 80 having a multi-layer structure even more flexible. The slit 89 may be formed in at least one of the first to fourth insulating layers 81 to 84. The position of the slit 89 in the FPC 80 is not particularly limited to the above.

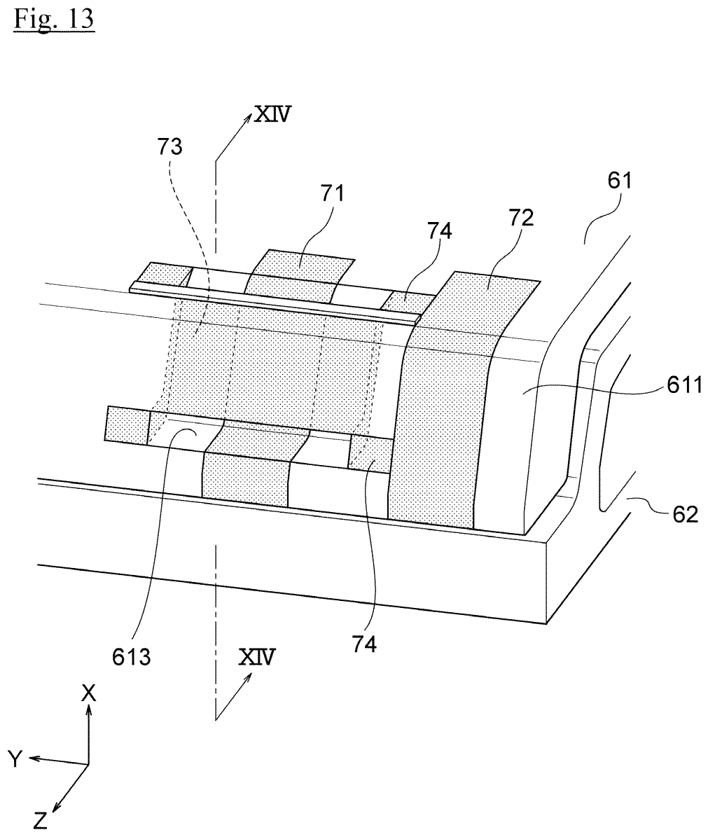

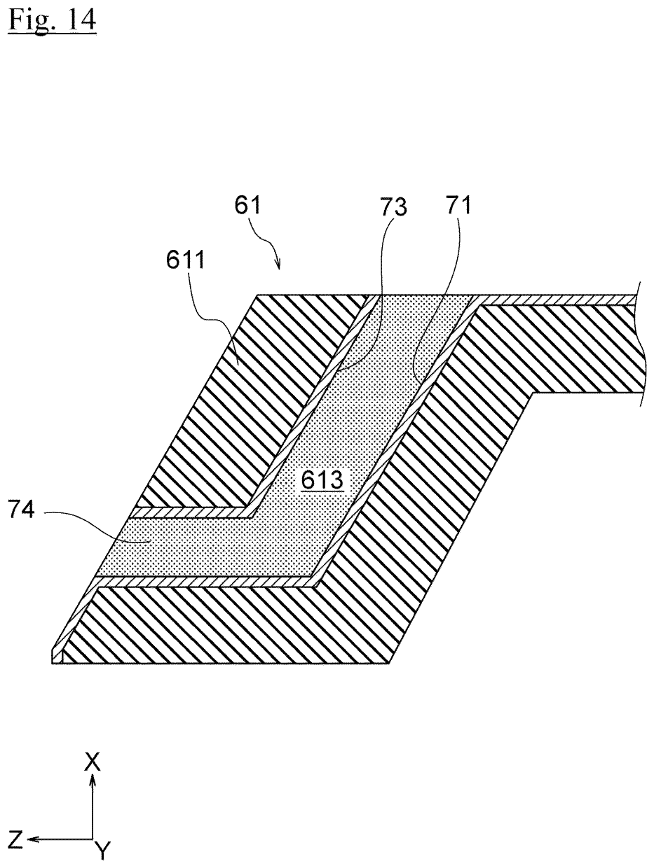

As shown in FIG. 13 and FIG. 14, a microstrip line structure may be formed in the contact portion 70. FIG. 13 is a perspective view showing the contact part 70 formed on the front end part 611 of the pressing member 60 in one or more embodiments. FIG. 14 is a cross-sectional view showing the front end part 611 of the pressing member 60 in one or more embodiments and is a view taken along line XIV-XIV in FIG. 13.

Specifically, as shown in FIG. 13 and FIG. 14, the through hole 613 is formed in the front end part 611 of the pressing member 60, the signal contact part 71 is formed on one inner surface of the through hole 613 (the −Z side in the figure), and a third ground layer 73 is formed on the other inner surface of the through hole 613 (the +Z side in the figure). Therefore, the third ground layer 73 faces the signal contact part 71 with a gap between the third ground layer 73 and the signal contact part 71. The third ground layer 73 is electrically connected to the ground contact part 72 adjacent to the signal contact part 71 via a connection part 74. Therefore, it is possible to ensure good shielding performance up to a position closer to the pad 24.

As shown in FIG. 9, the FPC 80 does not have the second and fourth insulating layers 82, 84 and a second ground layer 88 at both ends of the FPC 80 (both ends in the Z direction in the figure), and the signal lines 85 and the ground lines 86 are exposed toward the −X direction in the figure.

As shown in FIG. 5 to FIG. 7, the FPC 80 is attached to the pressing member 60 so that the fourth insulating layers 84 face the elastically deformation parti 61. At this time, one side (the +Z direction side in the figure) end 851 of the signal line 85 faces the signal contact part 71, and one side (the +Z direction side in the figure) end 861 of the ground line 86 faces the ground contact part 72. The end 851 of the signal line 85 and the signal contact part 71 are connected, for example, via a conductive film (ACF). Similarly, the end 861 of the ground line 86 and the ground contact part 72 are also connected, for example, via a conductive film (ACF). One side (the +Z direction side in the figure) end of the FPC 80 is fixed to the pressing member 60 via this conductive film.

Instead of the conductive film, the contact parts 71 and 72 and the lines 85 and 86 may be connected to each other by a conductive adhesive. Alternatively, the contact parts 71 and 72 and the lines 85 and 86 may be connected to each other by fixing the end of the FPC 80 to the pressing member 60 by mechanical means such as screws or clamps. Alternatively, the end of the FPC 80 may be fixed to the pressing member 60 and the contact parts 71 and 72 and the lines 85 and 86 may be connected to each other by reducing the pressure inside a tube in which the end of the FPC 80 and the pressing member 60 are encased. Alternatively, when the contact parts 71 and 72 are thin films, the contact parts 71 and 72 and the lines 85 and 86 may be connected to each other during the above-described insert molding.

As described above, the pressing member 60 and the electrical connection member 80 are fixed only at the front end portion of the electrical connection member 80, and the pressing member 60 and the electrical connection member 80 are not fixed to each other at any portion other than the front end portion. Therefore, the electrical connection member (FPC) 80 can be relatively freely deformed with respect to the pressing member 60. The pressing member 60 and the electrical connection member 80 may be fixed to each other at any portion other than the front end portion of the electrical connection member 80 by an adhesive or the like.

The contact terminal 50 described above is supported by the wiring board 90. Although not particularly limited, the contact terminal 50 is supported by the wiring board 90 by fixing the supporting part 63 of the pressing member 60 to the edge portion of the wiring board 90 via the fixing member 95. The method of fixing the contact terminal 50 to the wiring board 90 is not particularly limited to the above.

The wiring board 90 is a rigid wiring board including a substrate (base material) 91, signal lines 92, and ground lines 93. The substrate 91 is made of an electrically insulating material such as, for example, glass epoxy resin. The signal lines 92 and the ground lines 93 are disposed on the upper surface of the substrate 91. The signal lines 92 and the ground lines 93 extend linearly from the front side (the +Z direction side in the figure) end of the wiring board 90 toward the rear side (the −Z direction side in the figure). The signal line (example of a second conductive path) 92 and the ground line (example of a second conductive path) 93 are disposed with a space between the signal line 92 and the ground line 93. The signal lines 92 and the ground lines 93 are formed by etching a copper foil into a predetermined shape. Although not specifically illustrated, the wiring board 90 includes a ground layer inside the wiring board 90. The signal lines 92 and the ground lines 93 may pass through the inside of the wiring board 90.

The number of lines 92 and 93 included in the wiring board 90 is not particularly limited to the above and can be set according to, for example, the number of contact parts 70 included in the contact terminal 50. Furthermore, the shape and arrangement of the lines 92 and 93 included in the wiring board 90 are not particularly limited to the above. Instead of replacing (swapping) the coaxial cable 100, the shape and arrangement of the lines 92 and 93 of the wiring board 90 may be changed.

The FPC 80 of the contact terminal 50 supported by the wiring board 90 is connected to the wiring board 90. Specifically, as shown in FIG. 6, the other side (−Z direction side in the figure) end 852 of the signal line 85 of the FPC 80 faces one side (+Z direction side in the figure) end 921 of the signal line 92 of the wiring board 90, and the other side (−Z direction side in the figure) end 862 of the ground line 86 of the FPC 80 faces one side (+Z direction side in the figure) end 931 of the ground line 93 of the wiring board 90. The ends 852 and 921 of the signal lines 85 and 92 are connected to each other, for example, via a conductive film (ACF). Similarly, the ends 862 and 931 of the ground lines 86 and 93 are also connected to each other, for example, via a conductive film (ACF).

In FIG. 3 to FIG. 5, since the lower terminal assembly 40 has two contact terminals 50 respectively connected to the upper and lower surfaces of the wiring board 90, the wiring board 90 has the lines 92 and 93 on the upper and lower surfaces. The two contact terminals 50 are disposed so that the deformation limiting parts 62 of the pressing members 60 are in contact with each other. In FIG. 3 to FIG. 5, the upper terminal assembly 40 may include two upper and lower contact terminals 50. Although only one contact terminal 50 is disposed in the longitudinal direction of (Y direction in the figure) the wiring board 90 in FIG. 3 and FIG. 4, in reality, a plurality of contact terminals 50 are disposed in the longitudinal direction (Y direction in the figure) of the wiring board 90. Alternatively, one contact terminal 50 may have a width corresponding to the entire area of the wiring board 90 in the longitudinal direction (Y direction in the figure) of the wiring board 90.

The coaxial cable 100 is connected to the terminal assembly 40 described above. Specifically, as shown in FIG. 5 and FIG. 6, the inner conductor 101 of the coaxial cable 100 is connected to the other side (the −Z direction side in the figure) end 922 of the signal line 92 of the wiring board 90 by soldering or the like. Furthermore, the outer conductor 102 (e.g., a braided shield) of the coaxial cable 100 is connected to the other side (the −Z direction side in the figure) end 932 of the ground line 93 of the wiring board 90 via a connection member 105.

As shown in FIG. 2, the DSA 20 is attached to the motherboard 30 by fixing the wiring board 23 of the DSA 20 to the wiring board 90 of the terminal assembly 40 with bolts 25. As the bolts 25 are fixed, all of the pads 24 of the DSA 20 are simultaneously brought into contact with and are pressed against all of the contact parts 70 included in all of the terminal assemblies 40, and the contact parts 70 electrically connect the DSA 20 and the motherboard 30. The method of fixing the DSA 20 to the motherboard 30 is not limited to the above, and may be, for example, a mechanical clamp or the like.

In one or more embodiments, since the pressing member 60 and the electrical connection member 80 are mutually independent members, it is possible to reduce the mutual constraints between the designing of the pressing member 60 and the designing of the electrical connection member 80, and it is possible to improve the degree of freedom in the designing of the contact terminal 50.

Further, in one or more embodiments, since the pressing member 60 and the electrical connection member 80 are mutually independent members, it is possible to realize a variety of pressing forces and spring strokes while maintaining the electrical performance by changing the shape of the pressing member 60 without changing the electrical connection member 80.

Furthermore, in one or more embodiments, since the pressing member 60 and the electrical connection member 80 are mutually independent members, it is possible to use an FPC as the electrical connection member 80, and a transmission line with transmission performance (such as the above-mentioned impedance matching and shielding performance) for transmitting high-frequency signals can be designed independently of the design of the pressing member 60.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

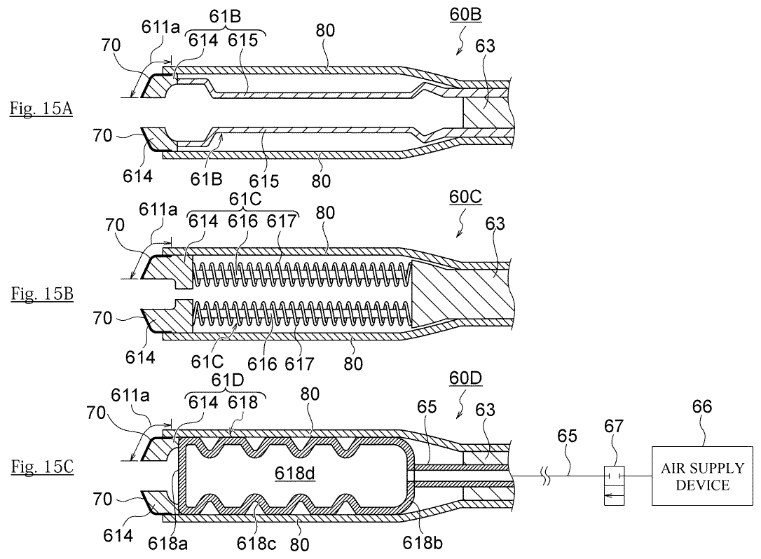

For example, although the elastic deformation part 61 of the pressing member 60 of the contact terminal 50 includes the resin spring in the above-described embodiments, the elastic deformation part 61 may include a metal spring or an air spring. FIG. 15A to FIG. 15C are cross-sectional views showing the contact terminals 60B to 60D that is the first to third modifications of the pressing member in one or more embodiments.

The elastic deformation part 61B of the pressing member 60B shown in FIG. 15A includes a front end member (front end part) 614 and a leaf spring (spring part) 615. The front end member 614 is fixed to the front end of the leaf spring 615. The front end member 614 is made of an electrically insulating material. Although not particularly limited, for example, a resin material can be exemplified as a specific material of which the front end member 614 is made. The contacting part 70 is disposed on the front end region 611a of the front end member 614. Similar to the elastic deformation part 61 shown in FIG. 6 and FIG. 7 described above, the plurality of contact parts 70 are disposed on the single (one) front end member 614 (the same front end member 614). Therefore, it is possible to ensure the relative positional relationship between the contact parts 70, and it is possible to suppress the occurrence of a short circuit between the adjacent pads 24 via the contact part 70. The electrical connection member 80 is connected to the contact parts 70 disposed on the front end member 614.

On the other hand, the leaf spring 615 is made of a metal material and can be elastically deformed when the front end member 614 is pressed by the pad 24. That is, the pressing member 60B includes a metal spring. The rear end part of the leaf spring 615 is supported by the supporting part 63.

The elastic deformation part 61C of the pressing member 60C shown in FIG. 15B includes a front end member (front end part) 614, a shaft 616, and a coil spring (spring part) 617. The front end member 614 is fixed to the front end of the shaft 616. On the other hand, the rear end of the shaft 616 is supported by a supporting part 63. The shaft 616 is extendable and contractable in the pressing direction (Z direction in the figure) of the pressing member 60C.

The coil spring 617 is made of a metal material, and the shaft 616 is inserted into the coil spring 617. The coil spring 617 is interposed between the front end member 614 and the supporting part 63 in a state where the coil spring 617 is compressed. That is, the pressing member 60C includes a metal spring. The coil spring 617 may be made of a resin material, and in this case, the pressing member 60C includes a resin spring.

The elastic deformation part 61D of the pressing member 60D shown in FIG. 15C includes a front end member (front end part) 614 and an air spring 618 (spring part). The air spring (pneumatic spring) 618 includes a front plate part 618a, a rear plate part 618b, and a bellows part 618c. The bellows part 618c is a cylindrical body that expands and contracts in the pressing direction (Z direction in the figure) of the pressing member 60C. The bellows part 618c is interposed between the front plate part 618a and the rear plate part 618b, and the front plate part 618a, the rear plate part 618b, and the bellows part 618c form an air chamber (sealed space) 618d that airtightly contains air. The front end member 614 is fixed to the front plate part 618a of the air spring 618. When the front end member 614 is pressed by the pad 24, the air spring 618d compresses and pushes contact part 70 back toward the pad 24. Although the air spring 618 is supported by the supporting part 63 via the pipe 65 in the example shown in FIG. 15C, the method of supporting air spring 618 is not particularly limited to this, for example, the air spring 618 may be directly fixed to the supporting part 63.

As shown in FIG. 15C, an air supply device 66 may be connected to the air spring 618 via the pipe 65. The valve 67 is disposed on the pipe 65. The air chamber 618d of the air spring 618 can be sealed or the air chamber 618d can be communicated with the air supply device 66 by opening and closing the valve 67. The pressure in the air chamber 618d can be adjusted by opening the valve 67 and supplying air from the air supply device 66. As a specific example of the air supply device 66, a pump can be exemplified. When the air supply device 66 is not connected to the air spring 618, the air chamber 618d is a sealed space filled with air.

Although the electrical connection member 80 is constituted by a single FPC in the above-described embodiments, the electrical connection member 80 may be divided. In this case, the contact terminal 50 includes a plurality of FPCs. Alternatively, a fine coaxial cable may be used as the electrical connection member 80 instead of the FPC.

### EXPLANATIONS OF LETTERS OR NUMERALS

1 . . . Device testing apparatus
10 . . . Tester
20 . . . DSA
21 . . . Socket
23 . . . Wiring board
24 . . . Pad
30 . . . Mother board
40 . . . Terminal assembly
50 . . . Contact terminal
60, 60B to 60D . . . Pressing member
61, 61B to 61D . . . Elastic deformation part
611 . . . Front-end part
612 . . . Spring part
613 . . . Front-end member
615 . . . Leaf spring
616 . . . Shaft
617 . . . Coil spring
618 . . . Air spring
62 . . . Deformation limiting part
621 . . . Abutting part
63 . . . Supporting part
70 . . . Contact part
71 . . . Signal contact part
72 . . . Ground contact part
73 . . . Third ground layer
74 . . . Connection part
80 . . . Electrical connection member (FPC)
81 to 84 . . . First to fourth insulating layers
85 . . . Signal line
851 and 852 . . . Ends
86 . . . Ground line
87 and 88 . . . First and second insulating layers
90 . . . Wiring board
91 . . . Substrate
92 . . . Signal line
921 and 922 . . . Ends
93 . . . Ground line
931 and 932 . . . Ends
100 . . . Coaxial cable
110 . . . Test head
120 . . . Main frame
130 . . . Handler
200 . . . DUT

What is claimed is:

1. A contact terminal comprising:
one or more contact parts that contact a conductive member;
a pressing member that presses the one or more contact parts relative to the conductive member; and
an electrical connection member, independent from the pressing member, comprising one or more conductive paths connected to the one or more contact parts.

2. The contact terminal according to claim 1, wherein the pressing member comprises one or more elastic deformation parts that elastically deform when the pressing member presses the one or more contact parts relative to the conductive member.

3. The contact terminal according to claim 2, wherein the one or more conductive paths have a constant electrical length regardless of deformation of the one or more elastic deformation parts.

4. The contact terminal according to claim 2, wherein an entirety of a circumference of the one or more conductive paths is surrounded by an insulator of the electrical connection member.

5. The contact terminal according to claim 2, wherein the one or more elastic deformation parts each comprise:
a resin spring that elastically deforms when the pressing member presses the one or more contact parts relative to the conductive member;
a metal spring that elastically deforms when the pressing member presses the one or more contact parts relative to the conductive member; or
an air spring that gets compressed when the pressing member presses the one or more contact parts relative to the conductive member.

6. The contact terminal according to claim 2, wherein
the pressing member is composed of a resin material, and
the one or more elastic deformation parts each comprise a resin spring that elastically deforms when the pressing member presses the one or more contact parts relatives to the conductive member.

7. The contact terminal according to claim 6, wherein
each of the elastic deformation parts corresponds to a corresponding contact part of the contact parts; and
the elastic deformation parts are integral.

8. The contact terminal according to claim 1, wherein the electrical connection member further comprises a flexible printed circuit board comprising the conductive paths connected to the contact parts.

9. The contact terminal according to claim 8, wherein the flexible printed circuit board further comprises:
a first insulating layer on which the conductive paths are disposed; and
a second insulating layer disposed on the first insulating layer and covering the conductive paths.

10. The contact terminal according to claim 9, wherein the conductive paths are arranged on the first insulating layer with a space between adjacent conductive paths of the conductive paths.

11. The contact terminal according to claim 9, wherein the flexible printed circuit board has a slit between adjacent conductive paths of the conductive paths.

12. The contact terminal according to claim 10, wherein the conductive paths include:
ground lines; and
signal lines each disposed between adjacent ground lines of the ground lines.

13. The contact terminal according to claim 12, wherein the flexible printed circuit board further comprises a ground layer disposed on the first insulating layer and facing the signal lines via the first insulating layer.

14. The contact terminal according to claim 12, wherein the flexible printed circuit board further comprises a ground layer disposed on the second insulating layer and facing the signal lines via the second insulating layer.

15. The contact terminal according to claim 12, wherein the contact parts include:
a signal contact part connected to one of the signal lines; and
a ground contact part connected to one of the ground lines.

16. The contact terminal according to claim 15, further comprising:
a ground layer electrically connected to the ground contact part, wherein
the pressing member has a through hole through which the signal contact part passes, and
the ground layer is disposed in the through hole and faces the signal contact part with a gap.

17. The contact terminal according to claim 1, wherein the one or more contact parts comprise a metal layer disposed on a front end part of the pressing member.

18. The contact terminal according to claim 17, wherein
the metal layer extends linearly, and
Lb<La× 1/10 is satisfied where
La is a length of the one or more conductive paths, and
Lb is a length of the metal layer.

19. The contact terminal according to claim 17, wherein the contact parts are disposed on the front end part of the pressing member.

20. The contact terminal according to claim 1, wherein the pressing member comprises:
an elastic deformation part that elastically deforms when the pressing member presses the one or more contact parts relative to the conductive member; and
a supporting part that supports the elastic deformation part.

21. The contact terminal according to claim 20, wherein
the pressing member is composed of a resin material, and
the elastic deformation part is integral with the supporting part.

22. The contact terminal according to claim 20, wherein a virtual line, passing through a front end of the pressing member, is parallel to and shifted from a center line of the supporting part.

23. The contact terminal according to claim 1, wherein the pressing member comprises:
an elastic deformation part that elastically deforms when the pressing member presses the one or more contact parts relative to the conductive member; and
a deformation limiting part that limits an elastic deformation of the elastic deformation part by contacting the conductive member.

24. The contact terminal according to claim 23, wherein
the pressing member is composed of a resin material, and
the elastic deformation part is integral with the deformation limiting part.

25. The contact terminal according to claim 24, wherein the pressing member further comprises a supporting part that supports and is integral with the elastic deformation part and the deformation limiting part.

26. A terminal assembly comprising:
contact terminals each comprising:
a contact part that contacts a conductive member;
a pressing member that presses the contact part relative to the conductive member; and
an electrical connection member, independent from the pressing member, comprising a first conductive path connected to the contact part; and
a supporting member that supports the contact terminals.

27. The terminal assembly according to claim 26, wherein the supporting member comprises a wiring board comprising a second conductive path connected to the first conductive path.

28. A device testing apparatus that the tests a device under test (DUT), the device testing apparatus comprising:
a first conductive member;
a second conductive member; and
a terminal assembly comprising:
contact terminals each comprising:
a contact part that contacts the first conductive member;
a pressing member that presses the contact part relative to the first conductive member; and
an electrical connection member, independent from the pressing member, comprising a conductive path connected to the contact part; and
a supporting member that supports the contact terminals, wherein
the conductive path of each of the contact terminals is electrically connected to the second conductive member, and
the contact terminals electrically connect the first conductive member and the second conductive member.
